(19) United States
(12) Patent Application Publication
(10) Pub. No.: US 2014/0232411 A1
(43) Pub. Date: Aug. 21, 2014

(54) SYSTEM AND METHOD FOR BATTERY MONITORING

(71) Applicant: KPIT Cummins Infosystems Ltd., Pune (IN)

(72) Inventors: Vinay Govind Vaidya, Pune (IN); Tarun Kancharla, Hyderabad (IN)

(73) Assignee: KPIT Cummins Infosytems Ltd, Pune (IN)

(21) Appl. No.: 14/348,540

(22) PCT Filed: Sep. 18, 2012
(86) PCT No.: PCT/IN2012/000626

§ 371 Date: Mar. 28, 2014

(30) Foreign Application Priority Data
Sep. 30, 2011 (IN) 2779/MUM/2011

(51) Int. Cl. G01R 31/36

(52) U.S. Cl. CPC G01R 31/3648
USPC 324/426

(57) ABSTRACT

A method and system for estimating the state-of-charge (SOC) and state-of-health (SOH) of a battery is disclosed. The method of the invention accurately determines the battery SOC by estimating the values of the recurring constants determined by the battery parameters based on the current and SOC values obtained during the charging and discharging cycle of the battery.

### FIELD OF INVENTION

The field of invention generally relates to determining the health of a battery and more specifically relates to determining state of charge of a battery and battery degradation.

### BACKGROUND OF INVENTION

A battery management system is used to determine State of Charge (SOC) and State of Health (SOH) of a battery. SOH of the battery gives the percentage degradation of the battery. SOC of a battery is the equivalent of a fuel gauge for a battery or a battery pack and provides the battery capacity. In other words, SOC is the ratio of the charge stored in the battery to the maximum charge that the battery can hold. SOC is usually expressed in terms of percentage. It is quite useful to determine the battery SOC for various applications. Battery SOC when estimated provides an indication of how much charge is remaining in the battery and how long it can be used for a particular application.

SOC of a battery is directly related to charge (Q) of the battery. As per the fundamental equations of Physics that are known in art, an electric current is flow of charge, given by

I=dQ/dt

Total charge built up for a given time, taking the time integral over a period, is given by

Q=∫I dt

Thus, theoretically, change in the state-of-charge (SOC) of the battery is proportional to the current that is drawn out of the battery or is put in to the battery over a time period ‘t’. However, batteries are of various types and characteristics of the battery depend on its type. The battery characteristics like internal resistance, discharge curve, capacity, etc. depend on various parameters like age of battery, battery usage, temperature, etc. The battery characteristics change with a change in battery parameters as well as external conditions.

The existing methods do not provide an accurate SOC estimation as they are dependent on parameters of the battery which change with age, usage, etc. Further, the constants and errors in the equations used for SOC estimation are not accounted and compensated for leading to an inaccurate SOC estimation. The existing methods for battery SOH estimation do not provide for determining age of the battery or battery degradation. Therefore, there is a need for a method that can correct for errors in the SOC estimation.

### SUMMARY OF INVENTION

The present invention discloses a method and system for estimating accurate State of Charge (SOC) and State of Health (SOH) of a battery comprising alternate use of a correction mechanism utilizing a function dependent on temperature of the battery and degradation of the battery and an exponential factor which is dependent on the battery current and the battery temperature and a correction loop, during charging-discharging cycle of the battery, wherein said method and system involves correction loop to correct/compensate any accumulation errors, caused due to battery parameters and determining age of the battery.

An object of the invention is to provide a system and method for determining the state-of-charge of a battery and battery degradation accurately over a period of time. The system and method of the invention may be used to determine the SOC of a battery and battery degradation either runtime, while the battery is being used or offline, while the battery is resting.

Another object of the invention is to provide a system and method for determining the state-of-charge of a battery which considers the battery characteristics that change over time and usage and hence provide for an accurate SOC estimation. The method of the invention compensates for the errors caused due to the parameters that change with a change in age, change in internal resistance, change in external temperature etc. and hence, affect the estimated SOC. With the method of the invention, SOC can be determined for all types of batteries.

A further object of the invention is to provide a method for estimating the battery degradation.

### BRIEF DESCRIPTION OF DRAWINGS

FIG. 1 illustrates a method for SOC estimation.

FIG. 2 illustrates a method for SOH estimation.

FIG. 3 illustrates a block diagram for the system of the invention.

FIG. 4 illustrates typical relation between Open Circuit Voltage (OCV) and State of Charge (SOC) of a battery.

FIG. 5 illustrates impedance model representation of a battery.

### DETAILED DESCRIPTION

The present invention uses a combination of a correction mechanism and a correction loop, accommodating for any differences in the voltage and current measurements. The present invention uses a correction mechanism method for calculating the SOC values. However, it accumulates error over time and hence a cumulative correction loop is used, which corrects for any errors in SOC estimation and which is based on the battery characteristics. It should be noted that both the approaches are not used simultaneously or at a given time instant, but either the correction mechanism or the correction loop is used.

SOC of a battery is directly related to charge (Q) of the battery. As per the fundamental equations of Physics that are known in art, an electric current is flow of charge, given by

I=dQ/dt.

Total charge built up for a given time, taking the time integral over a period, is given by

Q=∫I dt.

Thus, theoretically, change in the state-of-charge (SOC) of the battery is proportional to the current that is drawn out of the battery or is drawn in to the battery over a time period ‘t’. However, batteries are of various types and characteristics of the battery depend on its type. The battery characteristics like internal resistance, discharge curve, capacity, etc. depend on various parameters like age of battery, battery usage, etc. The battery characteristics change with a change in battery parameters.

Based on the fundamental charge and current equation, the method of the present invention uses a correction mechanism to estimate SOC, which accommodates various errors by taking into account the battery characteristics like the battery current, the battery temperature and the battery degradation.

According to the method of the invention, SOC estimation is given by,

SOC(t)=SOC(t−1)+I(t)*Δt*k*exp (−λ*I(t)) Eq. 1

Where SOC(t) and SOC(t−1) are the SOC at time instants t and t−1, I(t) is the current at t^{th} time instant, Δt is the time interval between the time instants, k=f(θ, % degradation), λ=f(θ) which are as defined below, θ is the temperature and % degradation is given by the SOH of the battery

$$λ = \{ \begin{matrix}{λ}_{1} & when ( t ) > 0 \\ - {λ}_{2} & otherwise\end{matrix}$$

The general equations of k and λ are

$$k = exp ( {b}_{1} + {c}_{1} * θ ) + {b}_{2} + {c}_{2} * \% degradation$$

$${λ}_{1} = \frac{1}{( {c}_{2} * θ + {b}_{2} )}$$

$${λ}_{2} = \frac{1}{( {c}_{4} * θ + {b}_{4} )}$$

Where b₁,b₂,b₃,b₄ are bias constants and c₁,c₂,c₃,c₄ are proportionality constants. The values of these constants are determined by experimentation and vary from battery to battery. For example, for the battery under experimentation (12 V 5.3 Ah lithium ion), the constants obtained are as listed below.

$$k = exp ( - 3 - θ / 12.5 ) + 5.2 + 0.057 * \% degradation$$

$${λ}_{1} = \frac{1}{100 * ( - 1.26 * θ + 76.5 )}$$

$${λ}_{2} = \frac{1}{100 * ( 0.72 * θ + 33.7 )}$$

The values for different constants are obtained by minimizing the error between SOC obtained and reference SOC during experimentation stages. Any of the standard optimization techniques can be used to obtain the constants.

Whenever the current is very low, usually at rest time or at the ending of a charge or discharge cycle, cumulative correction loop is employed to correct for any accumulation error.

The correction loop is used during the following conditions when:
There is a sudden drop or rise in voltage. It happens when the current suddenly goes to zero or when the current shoots up from zero. At these time instants, resistance is estimated and OCV is calculated from SOC=f(OCV) can be estimated.
ΔV and ΔI for consecutive time instants are both close to zero then the battery is considered as being rested

### SOC Estimation:

The following steps describe the method of estimation of SOC:

Step 1: Initially, voltage, current and temperature at an instant ‘t’ is obtained i.e. V (t), I (t) and θ (t) readings are obtained.

Step 2: The initial SOC from the previous recording is obtained, if it is the first time, and the SOC from SOC vs OCV characteristics is calculated as SOC(t)=f(OCV(t)) [OCV(t)=V(t) at t=0]

Step 3: If the change in the voltage and current measurements is approximately 0 i.e., |V(t)−V(t−1)|<TH_{—}1 and |I(t)−I(t−1)|<TH_{—}1 then OCV is calculated using the equation

OCV(t)=(1−Δt*α)*OCV(t−1)+Δt*α*V(t)

SOC(t)=f(OCV(t)) Eq. 2

where α is a constant which depends on temperature

Step 4: If there is a sudden drop or rise in voltage which usually happens during the start of end of a charging or discharging cycle, then resistance is computed. It is assumed that the OCV remains constant during this period so the change in current is not very high/infinitesimal. The resistance is estimated from R_est=abs(V(t)−V(t−1))/(I(t)−I(t−1)), then OCV is calculated using the equation

OCV(t)=(1−α)*OCV(t−1)+α*(max(abs(V(t),abs(V(t−1)))−max(abs(I(t),abs(I(t−1)))*R_est)

SOC(t)=f(OCV(t)) Eq. 3

Since the time taken to rest at lower temperatures is higher as compared to higher temperatures, the parameter a depends on temperature. For the battery under consideration, the value of α=1/200*exp(−0.07*θ)

Step 5: If the conditions in steps 3 and 4 are not satisfied, then Equation 3 is used to update SOC

SOC(t)=SOC(t−1)+I(t)*Δt*k*exp(−λ*I(t))

OCV(t)=f¹(SOC)

Step 6: Periodically, the value of k is updated when SOH is computed.

Step 7: Steps 2 to 6 are repeated for new samples obtained.

### SOH Estimation:

SOH is the ratio of actual battery capacity to the rated (fresh) battery capacity. Standard practice is to depict SOH in percentage (multiply the ratio by 100). This parameter indicates health of the battery. Typically, a battery is allowed to work in a vehicle till it reaches 70% of its rated capacity. The battery has to be replaced if the health falls below 70%.

The estimation of SOH follows estimation of present battery capacity, which is computed from the knowledge of change in SOC and the charge transfer obtained from Equation 1.

From Equation 1,

SOC(t)=SOC(t−1)+I(t)*DT*k*exp (−λ*I(t))

where k is a function of degradation

It is assumed that the battery capacity is unknown, and the value of k is estimated as

$$\text{?} = \frac{Soc ( {t}_{1} ) - SOC ( {t}_{2} )}{{\sum }_{i = {t}_{1}}^{{t}_{2}} \text{?} ( i ) * Δ t * exp ( - λ * \text{?} ( i ) )} \\ \text{?} \text{indicates text missing or illegible when filed} \qquad Eq . 4$$

where,

SOC(t₁)and SOC(₂) are SOC recorded at two different time instants when the battery is properly rested

kₑₛₜ is the estimated value of k

The SOC is obtained as a function of OCV in these cases.

From the estimated value of k, battery degradation is calculated as,

$$\begin{matrix} \% degradation = \frac{\text{?} + {b}_{2} - exp ( {b}_{1} + {c}_{1} * θ )}{{c}_{2}} & Eq . 5 \\ SOH = 100 - {\sum }_{i = 1}^{n} \frac{\% degradation ( i )}{n} \\ \text{?} \text{indicates text missing or illegible when filed} & Eq . 6\end{matrix}$$

For more accurate results of SOH, the value of kₑₛₜ should be calculated only when the difference in the SOC obtained between two time instants is sufficient, say 40.

Since SOH is a slow moving parameter and multiple charging and discharging cycles are involved for the value to change appreciably, an average of degradations obtained over multiple cycles to obtain and accurate value of SOH.

Step 1: The SOC (SOC_st) using OCV v/s SOC characteristics at time instant t1 is calculated when the battery is properly rested

Step 2: The accumulation sum is computed

SumI=SumI+I(t)*λt*exp(−λ*I(t))

Step 3: SOC(SOC_end) at another time instant t2 is calculated when the battery is rested

Step 4: kₑₛₜ using Eq.4 computed if |SOC_st−SOC_end|>40 or otherwise step 1 repeated.

Step 5: % degradation of the battery is computed as

$$\% degradation = \frac{\text{?} + {b}_{2} - exp ( {b}_{1} + {c}_{1} * θ )}{{c}_{2}}$$

$$\text{?} \text{indicates text missing or illegible when filed}$$

Step 6: The average of % degradation over multiple cycles (say n cycles) is calculated as

$${\sum }_{i = 1}^{n} \frac{\% degradation ( i )}{n}$$

Step 7: SOH is calculated as

$$SOH = 100 - {\sum }_{i = 1}^{n} \frac{\% degradation ( i )}{n}$$

Accordingly, a method and system for estimating accurate State of Charge (SOC) and State of Health (SOH) of a battery comprises alternate use of a correction mechanism utilizing a function dependent on temperature of the battery and degradation of the battery and an exponential factor which is dependent on the battery current and the battery temperature and a cumulative correction loop, during charging-discharging cycle of the battery, wherein said method and system involves correction loop to correct/compensate any accumulation errors, caused due to battery parameters and determining age of the battery.

The said correction loop, called in the method and system, is employed while battery current at consecutive time instants being close to zero while voltage remains constant or, when current suddenly drops to zero or rises from zero. The correction loop employed computes the resistance of the battery.

During the estimation of SOC of the battery, while the correction loop is not being used, the method utilizes a function (k) dependent on temperature of the battery and degradation of the battery and a correction exponential factor which is dependent on the battery current and the battery temperature.

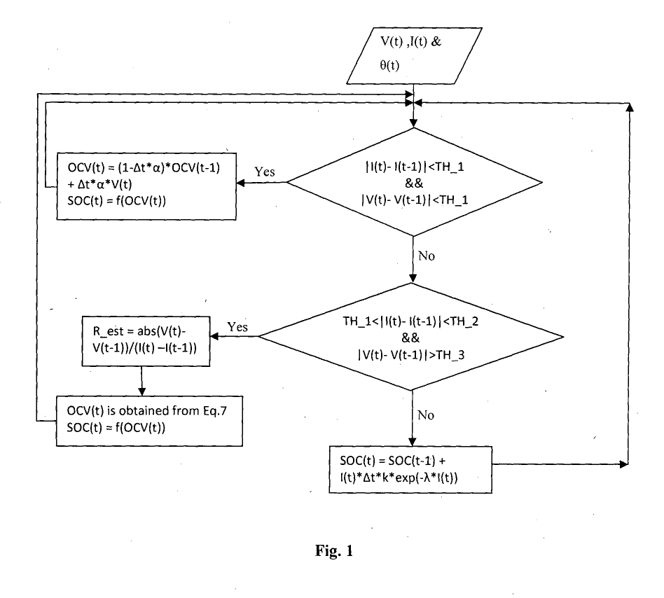

In a preferred embodiment, as illustrated in FIG. 1, the method consists of measuring initial values of battery current, voltage and temperature; determining initial value of battery SOC from previous recording or alternately calculating SOC from known corresponding OCV values if there is no previous record; determining SOC at an instant ‘t’ by employing correction loop if battery current at consecutive instants is less than a threshold TH_{—}1, which is close to zero; determining SOC at an instant ‘t’ by employing correction loop if there is a sudden drop in or rise in voltage during start or end of charging-discharging cycle, thus computing resistance and assuming OCV remains constant thereby change in battery current is infinitesimal; updating SOC employing correction loop if the stated conditions are not satisfied; computing State of Health (SOH) of the battery thereby periodically updating value of the function dependent on temperature of the battery and degradation of the battery k. This procedure is repeated for new samples obtained.

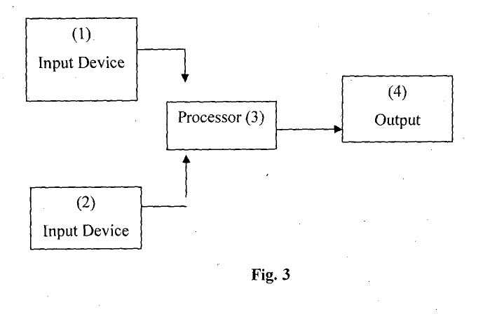

As illustrated in FIG. 3, the system disclosed in the present invention consists of a first input device (1), a second input device (2), a processor (3) and an output device (4). The processor (4) computes battery SOC based on the provided input values.

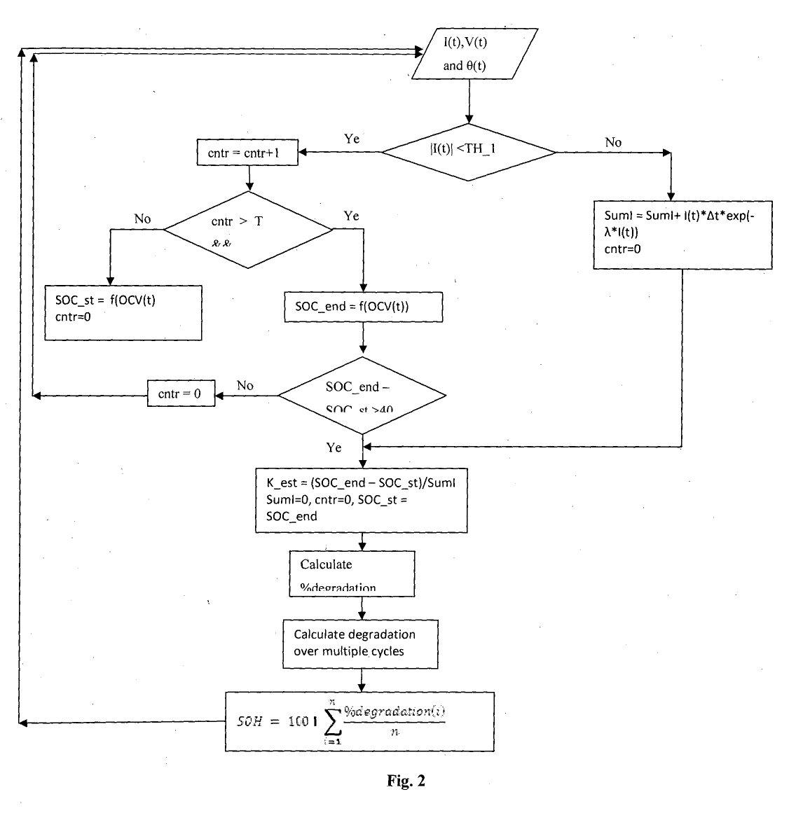

As illustrated in FIG. 2, the steps for calculating SOH consists of computing kₑₛₜ when battery properly rested; computing percentage degradation of the battery; calculating average of percentage degradation over multiple cycles; calculating SOH using values which are calculated previously.

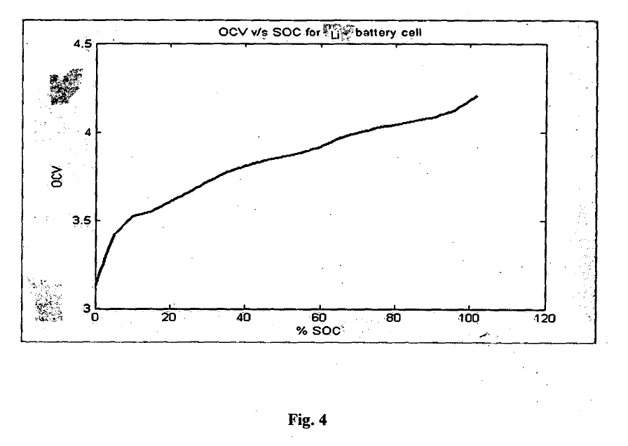

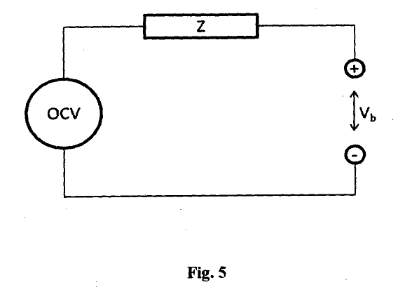

The steps for computing kₑₛₜ during calculation of said SOH consists of calculating initial battery SOC using known corresponding OCV values at an instant t1 when battery is properly rested; computing accumulation sum; calculate final battery SOC at another instant t2; compute kₑₛₜ if difference between initial and final battery SOC being greater than 40, otherwise repeating previous steps. The relation between SOC and OCV to calculate initial SOC is shown in FIG. 4, whereas FIG. 5 illustrates the impedance model representation of a battery.

The method and system of the invention maybe utilized to determine SOC for various types of batteries and various applications. SOC maybe determined for batteries used in various applications, like hybrid vehicle battery, electric vehicle battery, an inverter battery, etc. Additionally, the battery SOC maybe determined either online, while the battery is in use or offline, while the battery is resting. The above examples, will serve to illustrate the practice of this invention being understood that the particular shown by way of example, for purpose of illustrative discussion of preferred embodiment of the invention and are not limiting the scope of the invention.

1-10. (canceled)

11. A method for estimating a State of Charge (SOC) and State of Health (SOH) of a battery, the method comprising:
applying a correction mechanism utilizing a function dependent on a temperature of the battery and a degradation of the battery and an exponential factor dependent on a current of the battery and the temperature of the battery; and
applying a cumulative correction loop to compensate for one or more accumulation errors caused due to one or more battery parameters, including an age of the battery;
wherein the correction mechanism and the cumulative correction loop are applied at different times and are not applied simultaneously.

12. The method of claim 11, wherein said cumulative correction loop is applied during one or more of the following conditions:
the current at one or more consecutive time instants is close to zero while a voltage of the battery remains constant;
the current suddenly drops to zero; or
the currently suddenly rises from zero.

13. The method of claim 11, wherein said cumulative correction loop is applied when the current is suddenly dropping to zero or the current is rising from zero, and wherein the method further comprises computing a resistance of the battery.

14. The method of claim 11, wherein, when the cumulative correction loop is not being applied, the correction mechanism is applied to estimate the SOC of the battery.

15. The method of claim 11, wherein the SOC of the battery is determined either online, while the battery is being used, or offline, while the battery is being rested.

16. The method of claim 11, wherein the method further comprises:
(i) measuring an initial value of each of the current, the temperature, and a voltage of the battery;
(ii) when previous recording values of the SOC are available, determining an initial value of the SOC of the battery from the previous recording values, and when previous recording values of the SOC are not available, calculating the initial value of the SOC from known corresponding Open Circuit Voltage (OCV) values;
(iii) determining the SOC at a time ‘t’ by applying the cumulative correction loop when the current at one or more consecutive times is less than a threshold current that is close to zero.
(iv) determining the SOC at the time ‘t’ by applying the cumulative correction loop when there is a sudden drop in or rise in the voltage during a start or an end of a charging-discharging cycle, by computing a resistance and assuming the OCV remains constant and a change in current is infinitesimal;
(v) updating the SOC by applying the cumulative correction loop if conditions in steps (iii) and (iv) are not satisfied;
(vi) computing the SOH of the battery and periodically updating one or more parameters of the function dependent on the temperature of the battery and the degradation of the battery;
(vii) repeating steps (ii) to (vi) for one or more newly obtained samples.

17. The method of claim 1, further comprising calculating the SOC based on one or more input values received from one or more input devices.

18. The method of claim 17, further comprising calculating the SOH by:
computing an estimated degradation of the battery when the battery is properly rested;
computing a percentage degradation of the battery;
calculating an average of the percentage degradation over multiple cycles; and
calculating the SOH using at least one of the estimated degradation, the percentage degradation, or the average of the percentage degradation over multiple cycles.

19. The method of claim 18, wherein computing the estimated degradation of the battery comprises:
(i) calculating an initial value of the SOC using known corresponding OCV values at a time t1 when the battery is rested;
(ii) computing an accumulation sum;
(iii) calculating a final value of the SOC at another time t2; and
(iv) computing the estimated degradation of the battery when a difference between the initial value and the final value of the SOC is greater than 40 percent, or else repeating steps (i) to (iii).

20. A system for estimating a State of Charge (SOC) and State of Health (SOH) of a battery, the system comprising:
a processor configured to:
apply a correction mechanism utilizing a function dependent on a temperature of the battery and a degradation of the battery and an exponential factor dependent on a current of the battery and the temperature of the battery; and
apply a cumulative correction loop to compensate for one or more accumulation errors caused due to one or more battery parameters, including an age of the battery;
wherein the correction mechanism and the cumulative correction loop are applied at different times and are not applied simultaneously.

21. The system of claim 20, wherein the processor is configured to apply said cumulative correction loop during one or more of the following conditions:
the current at one or more consecutive time instants is close to zero while a voltage of the battery remains constant;
the current suddenly drops to zero; or
the currently suddenly rises from zero.

22. The system of claim 20, wherein the processor is configured to apply said cumulative correction loop when the current is suddenly dropping to zero or the current is rising from zero, and wherein the processor is further configured to compute a resistance of the battery.

23. The system of claim 20, wherein, when the cumulative correction loop is not being applied, the processor is configured to apply the correction mechanism to estimate the SOC of the battery.

24. The system of claim 20, wherein the processor is configured to determine the SOC of the battery either online, while the battery is being used, or offline, while the battery is being rested.

25. The system of claim 20, wherein the processor is further configured to:
(i) measure an initial value of each of the current, the temperature, and a voltage of the battery;
(ii) when previous recording values of the SOC are available, determine an initial value of the SOC of the battery from the previous recording values, and when previous recording values of the SOC are not available, calculate the initial value of the SOC from known corresponding Open Circuit Voltage (OCV) values;
(iii) determine the SOC at a time ‘t’ by applying the cumulative correction loop when the current at one or more consecutive times is less than a threshold current that is close to zero.
(iv) determine the SOC at the time ‘t’ by applying the cumulative correction loop when there is a sudden drop in or rise in the voltage during a start or an end of a charging-discharging cycle, by computing a resistance and assuming the OCV remains constant and a change in current is infinitesimal;
(v) update the SOC by applying the cumulative correction loop if conditions in steps (iii) and (iv) are not satisfied;
(vi) compute the SOH of the battery and periodically updating one or more parameters of the function dependent on the temperature of the battery and the degradation of the battery;
(vii) repeat steps (ii) to (vi) for one or more newly obtained samples.

26. The system of claim 20, further comprising a first input device, a second input device, and an output device

27. The system of claim 26, wherein the processor is configured to calculate the SOC based on one or more input values received from the first input device and the second input device.

28. The system of claim 27, wherein the processor is configured to calculate the SOH by:
computing an estimated degradation of the battery when the battery is properly rested;
computing a percentage degradation of the battery;
calculating an average of the percentage degradation over multiple cycles; and
calculating the SOH using at least one of the estimated degradation, the percentage degradation, or the average of the percentage degradation over multiple cycles.

29. The method of claim 28, wherein the processor is configured to compute the estimated degradation of the battery by:
(i) calculating an initial value of the SOC using known corresponding OCV values at a time t1 when the battery is rested;
(ii) computing an accumulation sum;
(iii) calculating a final value of the SOC at another time t2; and
(iv) computing the estimated degradation of the battery when a difference between the initial value and the final value of the SOC is greater than 40 percent, or else repeating steps (i) to (iii).
